(19) United States
(12) Patent Application Publication
(10) Pub. No.: US 2009/0140310 A1
(43) Pub. Date: Jun. 4, 2009

(54) SEMICONDUCTOR DEVICE AND METHOD FOR MANUFACTURING THE SAME

(76) Inventors: In-Hee Jang, Suwon-si (KR); Kun-Hyuk Lee, Dobong-gu (KR)

Correspondence Address: SHERR & VAUGHN, PLLC, 620 HERNDON PARKWAY, SUITE 200, HERNDON, VA, 20170, US

(21) Appl. No.: 12/326,900

(22) Filed: Dec. 3, 2008

(30) Foreign Application Priority Data
Dec. 3, 2007 (KR) 10-2007-0124454

(51) Int. Cl. H01L 27/105; H01L 21/02

(52) U.S. Cl. 257/298; 438/396; 257/E27.081; 257/E21.008

(57) ABSTRACT

A semiconductor device and a method for manufacturing the semiconductor device in which a micro controller unit (MCU) and a flash memory having the same structure as that of a logic circuit of the MCU are formed in the same chip.

The present application claims priority under 35 U.S.C. §119 to Korean Patent Application No. 10-2007-0124454 (filed on Dec. 3, 2007), which is hereby incorporated by reference in its entirety.

### BACKGROUND

Capacitors used in semiconductor devices are generally divided into capacitors having a poly-insulator-poly (PIP) structure and capacitors having a metal-insulator-metal (MIM) structure. Capacitors having the respective structures are properly selected according to purposes. As logic circuits of micro controller unit's (MCU) have been developed to go into sub-micron design rule (D/R), the capacitors have been changed from the PIP structure to the MIM structure. Further, in order to form a random system requiring an MCU and a flash memory, the MCU and the flash memory are connected on a board. On the other hand, in case that the MCU and the flash memory are not connected on the board but are formed in a single chip using a system-on-chip (SOC) technique to form a system, the composition of the system is advantageous and the probability of the malfunction of the system is lowered.

However, since the flash memory requires a complicated process, such as formation of a stacked gate, in case that the MCU and the flash memory are not formed in a single chip but are formed in respective chips to form a system, a multi-chip package (MCP) technique is used. Further, the flash memory applied to the above system does not require endurance exceeding a cycle of 100K, and is used to program the system only once when the system having a one time programmable (OTP) level is formed. Further, the flash memory applied to the system does not require a large memory capacity of 128 MB or 4 GB, but generally requires a small memory capacity of 4K bit.

FIG. 1 is a longitudinal-sectional view of a MCU logic structure. MCU logics are formed by combining semiconductor devices, such as a transistor, a capacitor, a diode, etc., which are formed in a single chip. FIG. 1 illustrates an MCU logic structure, in which a MOS transistor and a capacitor having a MIM structure are stacked in a single chip. As shown in FIG. 1, an isolation layer 2 to electrically isolate semiconductor devices from each other is formed in a semiconductor substrate 1. A gate insulating film 3 and a gate electrode 4 are formed in an active region on and/or over the semiconductor substrate 1. Source/drain regions 5 are formed in the semiconductor substrate 1 at both sides of the gate electrode 4 by impurity ion implantation. Thereby, the MOS transistor is formed. An interlayer insulating film 6 is formed on and/or over the entire surface of the semiconductor substrate 1 including the MOS transistor. A lower electrode 7 of the capacitor which is made of aluminum (Al), a dielectric film 8, which is made of silicon nitride (Si₃N₄), and an upper electrode 9 of the capacitor which is made of a titanium based layer or multi-layer such as (Ti/TiN), are sequentially stacked on and/or over the interlayer insulating film 6. Thereby, the capacitor having a MIM structure is formed. Via contact plugs 10 are respectively formed on and/or over the lower electrode 7 and the upper electrode 9 of the capacitor.

However, since such a MCU logic requires a complicated process, such as formation of a stacked gate, to form a flash memory, the flash memory and the MCU logic cannot be formed in a single chip.

### SUMMARY

Embodiments relate to a semiconductor device and a method for manufacturing the same in which a micro controller unit (MCU) and a flash memory are formed on the same chip such that the flash memory has a similar structure to that of a logic circuit of the MCU to simplify a semiconductor device manufacturing process, and a method for manufacturing the semiconductor device.

Embodiments relate to a semiconductor device in which a micro controller unit (MCU) and a flash memory are formed on and/or over the same chip such that the flash memory is designed to have the same structure as that of a logic circuit of the MCU.

Embodiments relate to a semiconductor device that may include at least one of the following: a semiconductor substrate having defined therein an MCU logic region and a flash memory region; first and second transistors respectively provided with first and second gate electrodes formed in the MCU logic region and the flash memory region; an interlayer insulating film formed on and/or over the entire surface of the substrate including the first and second transistors; a first contact plug formed in the interlayer insulating film on and/or over the second gate electrode in the flash memory region; and first and second capacitors respectively formed on and/or over the interlayer insulating film in the MCU logic region and the flash memory region.

In accordance with embodiments, the lower electrode of the second capacitor and the second gate electrode, formed in the flash memory region, may be electrically connected to the first contact plug, and thus, the second gate electrode, the first contact plug, and the lower electrode of the second capacitor may serve as a floating gate of a flash memory device, and the upper electrode of the second capacitor may serve as a control gate of the flash memory device.

Embodiments relate to a device that may include at least one of the following: a semiconductor substrate having an MCU logic region and a flash memory region defined therein; a first transistor having a first gate electrode formed in the MCU logic region; a second transistor having a second gate electrode formed in the flash memory region; an interlayer insulating film formed over the entire surface of the semiconductor substrate including the first and second transistors; a first contact plug formed in the interlayer insulating film exposing the second gate electrode; a first capacitor formed over the interlayer insulating film in the MCU logic region; and a second capacitor formed over the interlayer insulating film in the flash memory region electrically connected to the second gate electrode.

Embodiments relate to a method for manufacturing a semiconductor device that may include at least one of the following: providing a semiconductor substrate having an MCU logic region and a flash memory region defined therein; forming first and second transistors respectively provided with first and second gate electrodes in the MCU logic region and the flash memory region; forming an interlayer insulating film on and/or over the entire surface of the substrate including the first and second transistors; forming a first contact plug in the interlayer insulating film on and/or over the second gate electrode in the flash memory region; and forming first and second capacitors respectively on and/or over the interlayer insulating film in the MCU logic region and the flash memory region.

Embodiments relate to a method that may include at least one of the following: providing a semiconductor substrate having an MCU logic region and a flash memory region defined therein; and then simultaneously forming first and second transistors respectively provided with first and second gate electrodes in the MCU logic region and the flash memory region; and then forming an interlayer insulating film over the entire surface of the semiconductor substrate including the first and second transistors; and then forming a first contact plug in the interlayer insulating film exposing the second gate electrode in the flash memory region; and then forming first and second capacitors respectively over the interlayer insulating film in the MCU logic region and the flash memory region, wherein the second capacitor is electrically connected to the second gate electrode through the first contact plug.

Embodiments relate to a method that may include at least one of the following: providing a semiconductor substrate having an MCU logic region and a flash memory region defined therein; and then forming a first transistor having a first gate electrode in the MCU logic region; and then forming a second transistor having a second gate electrode in the flash memory region; and then forming a first insulating film over the entire surface of the semiconductor substrate including the first and second transistors; and then forming a first contact plug in the first insulating film and electrically connected to the second gate electrode in the flash memory region; and then forming a first capacitor including a first lower electrode, a first dielectric film and first upper electrode in the MCU logic region; and then forming a second capacitor including a second lower electrode, a second dielectric film and second upper electrode in the flash memory region; and then forming a second insulating film over the entire surface of the semiconductor substrate including the first and second capacitors; and then simultaneously forming a second contact plug in the second insulating film electrically connected to the first lower electrode, a third contact plug in the second insulating film electrically connected to the first upper electrode and a fourth contact plug in the second insulating film electrically connected to the second upper electrode.

### DRAWINGS

FIG. 1 is a longitudinal-sectional view of a conventional MCU logic structure.

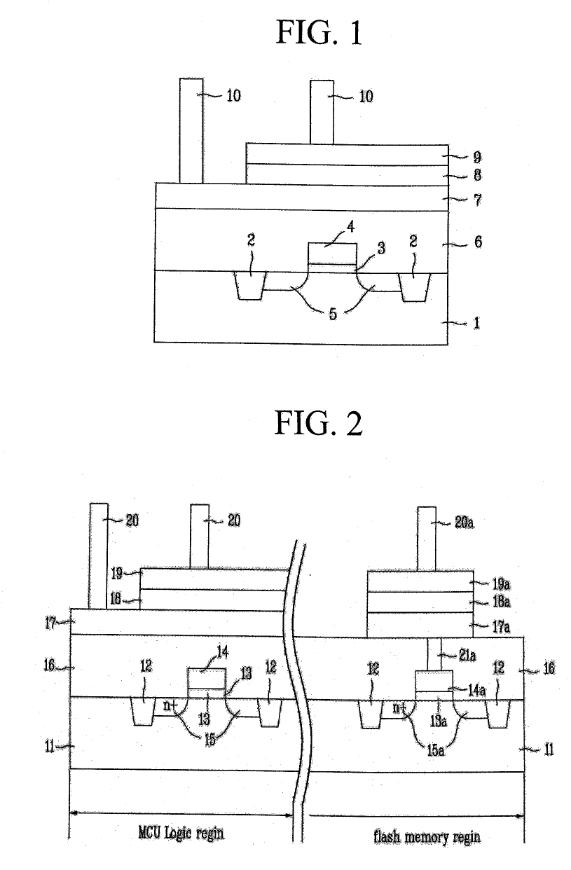

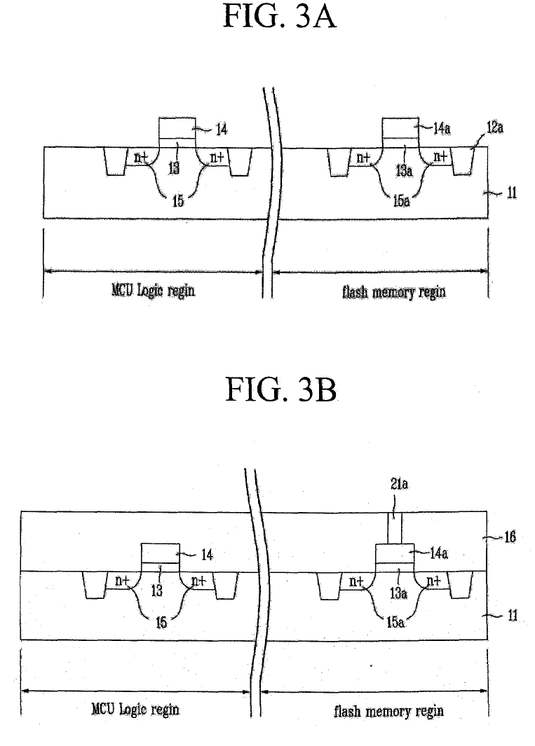

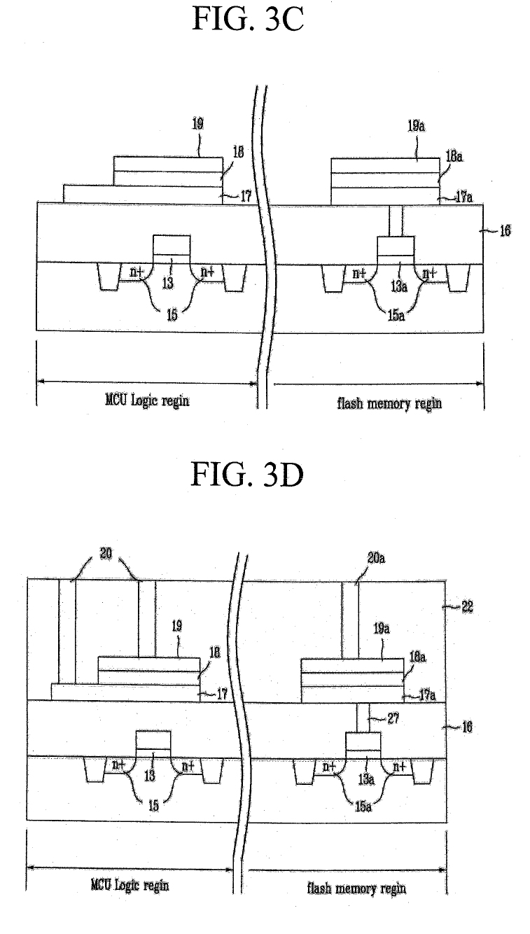

Example FIGS. 2 and 3 illustrate a semiconductor device and a method for manufacturing the same in which an MCU and a flash memory are formed in a single chip, in accordance with embodiments.

### DESCRIPTION

As illustrated in example FIG. 2, a semiconductor device, in which an MCU and a flash memory are formed in a single chip may include an isolation film 12 formed on and/or over a semiconductor substrate 11 having an MCU logic region and a flash memory region. The isolation film 12 serves to electrically isolate semiconductor devices from each other. Gate insulating films 13, 13a and gate electrodes 14, 14a are respectively formed in active regions of the MCU logic region and the flash memory region. Source/drain regions 15, 15a are respectively formed in the semiconductor substrate 11 at both sides of the gates 14, 14a by impurity ion implantation, thereby producing MOS transistors respectively in the MCU logic region and the flash memory region. An interlayer insulating film 16 is formed on and/or over the entire surface of the semiconductor substrate 11 including the respective MOS transistors. A first contact plug 21a is formed in the interlayer insulating film 16 on and/or over the gate electrode 14a in the flash memory region.

Lower electrodes 17, 17a of capacitors are formed on and/or over the interlayer insulating film 16 in the MCU logic region and the flash memory region. The lower electrodes 17, 17a may include a layer made of one selected from the group consisting of Al, Ti, Ta, Cu, and Mo, or any combination thereof in a multi-layered structure. Dielectric films 18, 18a, which may include a layer made of one selected from the group consisting of Si₃N₄, Al₂O₃, and TaO, are formed on and/or over the lower electrodes 17, 17a in the MCU logic region and the flash memory region. Upper electrodes 19, 19a of the capacitors, which may include a layer made of one selected from the group consisting of Al, Ti, Ta, Cu, and Mo, or have a multi-layered structure, may be formed on and/or over the upper electrodes 19, 19a in the MCU logic region and the flash memory region. Thereby, capacitors having a MIM structure are formed. Second contact plugs 20 are respectively formed on and/or over the lower electrode 17 and the upper electrode 19 of the capacitor in the MCU logic region. A second contact plug 20a is formed on and/or over the upper electrode 19a of the capacitor in the flash memory region.

The gate electrode 14a and the lower electrode 17a of the capacitor in the flash memory region are electrically connected by the first contact plug 21a. Therefore, the gate electrode 14a, the first contact plug 21a, and the lower electrode 17a of the capacitor in the flash memory region serve as a floating gate of a flash memory device. The upper electrode 19a of the capacitor in the flash memory region serves as a control gate of the flash memory device, and thus, the flash memory device has a comparatively small capacity.

Example FIGS. 3A to 3D are longitudinal-sectional views illustrating a method for manufacturing the semiconductor device in accordance with embodiments.

As illustrated in example FIG. 3A, isolation film 12 to electrically isolate semiconductor devices from each other is formed on and/or over a semiconductor substrate 11 having an MCU logic region and a flash memory region defined therein. Isolation film 12 is formed by forming trenches by selectively etching the semiconductor substrate 11 in device isolation regions and forming an insulating film such as an oxide film on and/or over the semiconductor substrate 11 and filing the trench. Portions of the insulating film is then selectively removed by a chemical mechanical polishing (CMP) process such that the insulating film remains only in the trenches, thus forming the isolation film 12. Gate insulating films 13, 13a and the gate electrodes 14, 14a are respectively formed in the active regions of the MCU logic region and the flash memory region by depositing a gate oxide film (tunnel oxide film) and a polysilicon layer (or a metal layer) on and/or over the entire surface of the semiconductor substrate 11 and selectively removing the gate oxide film and the polysilicon layer. Then, the source/drain regions 15, 15a are respectively formed by implanting high concentration n-type impurity ions into the semiconductor substrate 11 at both sides of the gate electrodes 14, 14a using the gate electrodes 14, 14a as masks. Thereby, MOS transistors are respectively formed in the regions.

As illustrated in example FIG. 3B, an interlayer insulating film 16 is formed on and/or over the entire surface of the semiconductor substrate 11 including the MOS transistors, and a contact hole is formed by selectively removing a portion of the interlayer insulating film 16 on and/or over the gate electrode 14a in the flash memory region. Then, a first contact plug 21 is formed by filling the contact hole with a material, such as tungsten, and carrying out a CMP process.

As illustrated in example FIG. 3C, a first metal layer is then formed on and/or over the interlayer insulating film 16 in the MCU logic region and the flash memory region. The first metal layer may include one selected from the group consisting of Al, Ti, Ta, Cu, and Mo, or any combination thereof in a multi-layered structure. Then a dielectric film, which may include a layer made of one selected from the group consisting of Si₃N₄, Al₂O₃, and TaO, are formed on and/or over the first metal layer in the MCU logic region and the flash memory region. A second metal layer, which may include a layer made of one selected from the group consisting of Al, Ti, Ta, Cu, and Mo, or any combination thereof in a multi-layered structure, may then be formed on and/or over the dielectric layer in the MCU logic region and the flash memory region. Thereby, capacitors having a MIM structure are formed including the lower electrodes 17, 17a, the dielectric films 18, 18a, and the upper electrodes 19, 19a by selectively removing the first and second metal layers and the dielectric film. The lower electrode 17a of the capacitor and the gate electrode 14a in the flash memory region are electrically connected by the first contact plug 21a.

As illustrated in example FIG. 3D, an interlayer insulating film 22 is formed on and/or over the entire surface of the semiconductor substrate 11 including the capacitors. Via contact holes are respectively formed exposing a portion of the lower electrode 17 and the upper electrode 19 of the capacitor in the MCU logic region and also the upper electrode 19a of the capacitor in the flash memory region. The second contact plugs 20, 20a are respectively formed in the via contact holes. The gate electrode 14a of the MOS transistor and the lower electrode 17a of the capacitor in the flash memory region, which are electrically connected by the first contact plug 21a, do not form a random circuit, but the gate electrode 14a, the lower electrode 17a of the capacitor, and the first contact plug 21 serve as a floating gate of the flash memory. The upper electrode 19a of the capacitor serves as a control gate of the flash memory. Thus, a flash memory having the same structure as that of the MCU logic region is formed in the flash memory region.

In accordance with embodiments, a flash memory, which has the same structure of a logic circuit of an MCU, and the MCU are formed in the same chip. Therefore, it is possible to simplify the constitution of a system and reduce the malfunction of the system.

Although embodiments have been described herein, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A device comprising:
a semiconductor substrate having an MCU logic region and a flash memory region defined therein;
a first transistor having a first gate electrode formed in the MCU logic region;
a second transistor having a second gate electrode formed in the flash memory region;
an interlayer insulating film formed over the entire surface of the semiconductor substrate including the first and second transistors;
a first contact plug formed in the interlayer insulating film exposing the second gate electrode;
a first capacitor formed over the interlayer insulating film in the MCU logic region; and
a second capacitor formed over the interlayer insulating film in the flash memory region electrically connected to the second gate electrode.

2. The device of claim 1, wherein each of the first and second capacitors has an MIM structure including a lower electrode, a dielectric film and an upper electrode.

3. The device of claim 2, wherein the lower electrode of the second capacitor and the second gate electrode are electrically connected to the first contact plug.

4. The device of claim 2, wherein the second gate electrode, the first contact plug, and the lower electrode of the second capacitor serve as a floating gate of a flash memory device and the upper electrode of the second capacitor serves as a control gate of the flash memory device.

5. The device of claim 2, wherein the upper and lower electrodes of the first and second capacitors are composed of a metal layer.

6. The device of claim 5, wherein the metal layer is one selected from the group consisting of Al, Ti, Ta, Cu, and Mo and any combination thereof in a multilayered structure.

7. The device of claim 2, wherein the dielectric film of the first and second capacitors one selected from the group consisting of Si₃N₄, Al₂O₃, and TaO.

8. A method comprising:
providing a semiconductor substrate having an MCU logic region and a flash memory region defined therein; and then
simultaneously forming first and second transistors respectively provided with first and second gate electrodes in the MCU logic region and the flash memory region; and then
forming an interlayer insulating film over the entire surface of the semiconductor substrate including the first and second transistors; and then
forming a first contact plug in the interlayer insulating film exposing the second gate electrode in the flash memory region; and then
forming first and second capacitors respectively over the interlayer insulating film in the MCU logic region and the flash memory region, wherein the second capacitor is electrically connected to the second gate electrode through the first contact plug.

9. The method of claim 8, wherein simultaneously forming the first and second capacitors comprises forming a MIM structure by sequentially stacking a lower electrode, a dielectric film, and an upper electrode.

10. The method of claim 9, wherein the lower electrode of the second capacitor and the second gate electrode are electrically connected to the first contact plug.

11. The method of claim 9, wherein the second gate electrode, the first contact plug, and the lower electrode of the second capacitor serve as a floating gate of a flash memory device and the upper electrode of the second capacitor serves as a control gate of the flash memory device.

12. The method of claim 9, wherein the upper and lower electrodes of the first and second capacitors are composed of a metal layer.

13. The method of claim 12, wherein the metal layer is one selected from the group consisting of Al, Ti, Ta, Cu, and Mo and any combination thereof in a multilayered structure.

14. The method of claim 9, wherein the dielectric film of the first and second capacitors one selected from the group consisting of Si₃N₄, Al₂O₃, and TaO.

15. A method comprising:
providing a semiconductor substrate having an MCU logic region and a flash memory region defined therein; and then
forming a first transistor having a first gate electrode in the MCU logic region; and then
forming a second transistor having a second gate electrode in the flash memory region; and then
forming a first insulating film over the entire surface of the semiconductor substrate including the first and second transistors; and then
forming a first contact plug in the first insulating film and electrically connected to the second gate electrode in the flash memory region; and then
forming a first capacitor including a first lower electrode, a first dielectric film and first upper electrode in the MCU logic region; and then
forming a second capacitor including a second lower electrode, a second dielectric film and second upper electrode in the flash memory region; and then
forming a second insulating film over the entire surface of the semiconductor substrate including the first and second capacitors; and then
simultaneously forming a second contact plug in the second insulating film electrically connected to the first lower electrode, a third contact plug in the second insulating film electrically connected to the first upper electrode and a fourth contact plug in the second insulating film electrically connected to the second upper electrode.

16. The method of claim 15, wherein the second gate electrode, the first contact plug, and the second lower electrode combine to serve as a floating gate of a flash memory device and the second upper electrode serves as a control gate of the flash memory device.

17. The method of claim 15, wherein the first lower electrode, the first upper electrode, the second lower electrode and the second upper electrode are composed of a metal layer.

18. The method of claim 17, wherein the metal layer is one selected from the group consisting of Al, Ti, Ta, Cu, and Mo and any combination thereof in a multilayered structure.

19. The method of claim 15, wherein the first and second dielectric films are one selected from the group consisting of Si₃N₄, Al₂O₃, and TaO.

20. The method of claim 15, wherein the first and second transistors comprise MOS transistors.
